(19) United States
(12) Patent Application Publication
(10) Pub. No.: US 2006/0094389 A1
(43) Pub. Date: May 4, 2006

(54) Push-pull amplifier and frequency converter circuit

(76) Inventor: Hideaki Dodo, Tokyo (JP)

Correspondence Address: SCULLY SCOTT MURPHY & PRESSER, PC, 400 GARDEN CITY PLAZA, SUITE 300, GARDEN CITY, NY, 11530, US

(21) Appl. No.: 10/526,724

(22) PCT Filed: Sep. 8, 2003
(86) PCT No.: PCT/JP03/11401

§ 371 Date: Sep. 6, 2005

(30) Foreign Application Priority Data
Sep. 9, 2002 (JP) 2002-262837

(51) Int. Cl. H03B 19/00; H04B 1/26

(52) U.S. Cl. 455/313; 455/207; 455/323; 327/113

(57) ABSTRACT

As an output amplifier of a frequency converter circuit, a push-pull amplifier that allows operating with a small consumption current and providing a high gain is used. Further, the push-pull amplifier is configured to have a voltage drop circuit to lower the collector potential of the upper transistor to the level lower than the potential of the power supply. The voltage drop circuit is configured to have, for example, a resistor inserted between the collector of the upper transistor and the power supply.

### TECHNICAL FIELD

The present invention relates to a frequency converter circuit used for a wireless communication system.

### BACKGROUND ART

Recently, a variety of services making use of wireless communication systems such as a portable telephone, a wireless LAN, Bluetooth or ITS (Intelligent Transport System) has been rapidly coming into wide use. In the field of mobile terminal devices used in such a wireless communication system, downsizing and weight reduction have been progressing together with a challenge to high functionality, and to the RF (Radio Frequency) section of the mobile terminal device, further reduction of power consumption has been required.

In the variety of the wireless communication systems described above, a frequency converter circuit for converting a signal frequency to another frequency is one of imperative key components. The frequency converter circuit is used in the transmitting system as a circuit for converting an IF (intermediate frequency) signal for signal processing, which has a comparatively low frequency, to an RF signal for transmission, which has a comparatively high frequency, through the use of a local oscillator frequency signal (hereinafter referred to an LO signal). The frequency converter circuit, in addition, serves in the receiving system as a circuit to convert an RF signal to an IF signal. In the above operations, the frequency converter circuit is required to reduce an LO signal component that leaks to the output side in order to eliminate a frequency component unnecessary for transmitting/receiving operation. The frequency converter circuit of the transmitting system, in particular, is more strictly required to reduce the LO signal component that leaks into the transmission output, because the frequencies of the LO and RF signals are near.

FIG. 1 illustrates a typical structure of a frequency converter circuit.

As represented in FIG. 1, frequency converter circuit 1 is configured to have mixer circuit 2 that converts the frequency of input signal (Pin) making use of LO signal (LO) and output amplifier 3 that amplifies the output signal of mixer circuit 2. Hereinafter, the output signal of mixer circuit 2 is referred to as a frequency converted signal and the output signal of output amplifier 3 is referred to as a frequency-converted output signal.

For mixer circuit 2 shown in FIG. 1, a double-balanced circuit called a Gilbert cell is widely used, capable of blocking the leakage of the LO signal component to the output side by taking advantage of a symmetry property of a differential circuit (for example, Japanese Patent Laid-Open Publication No. 11-74733 and Japanese Patent Laid-Open Publication No. 2002-124834). FIG. 2 represents an example of the circuit structure of this Gilbert cell.

As represented in FIG. 2, the Gilbert cell has a construction having input signal amplifier section 21 of a differential configuration that voltage-to-current converts an input signal (IF in FIG. 2) and also having switch section 22 provided with two differential circuits to supply as a frequency converted signal the result of mixing (multiplying) the input signal (IF) and the LO signal (LO) together. Because the Gilbert cell supplies as outputs the in-phase LO signal components of the same amplitude from the two output terminals, taking out the difference signal of the two outputs involves compensation of the LO signal components for each other.

FIG. 3 is a circuit diagram representing the construction of a conventional frequency converter circuit with a differential amplifier circuit used for the output amplifier shown in FIG. 1.

The frequency converter circuit shown in FIG. 3 is an example in which the above Gilbert cell constructs the mixer circuit and the differential amplifier circuit constructs the output amplifier. This circuit structure supplies two frequency converted signals provided from the mixer circuit, to transistors Q21 and Q22 that make up the differential amplifier and puts out a frequency-converted output signal, which is a difference signal of the input signals of transistors Q21 and Q22, from transistor Q 21.

In this circuit, if the input impedances of transistors Q 21 and Q 22 are equal, the load impedances connected with the two output terminals of the mixer circuit are equal and therefore the mixer circuit provides LO signal components having the same phase and the same amplitude. As a result, the two LO signal components are compensated for each other by the output amplifier made up of the differential amplifier circuit, causing the LO signal component leaked into the frequency-converted output signal to be reduced. For this reason, the differential amplifier circuit has been widely utilized as an output amplifier of a frequency converter circuit.

Alternatively, a push-pull amplifier as shown in FIG. 4 can also be used for output amplifier 3 for frequency converter circuit 1 shown in FIG. 1.

As shown in FIG. 4, the push-pull amplifier is structured to have upper transistor Q 31 supplied with a power-supply voltage at the collector and also emitter-grounded lower transistor Q 32, with the emitter of upper transistor Q 31 and the collector of the lower transistor Q 32 connected to each other. In the conventional push-pull amplifier shown in FIG. 4, the collector of upper transistor Q 31 is connected directly to power supply Vcc. In this circuit structure, upper transistor Q 31 operates as an emitter follower and lower transistor Q 32 operates as a grounded-emitter amplifier.

FIG. 5 is a circuit diagram illustrating the structure of a conventional frequency converter circuit using the push-pull amplifier shown in FIG. 4 as an output amplifier.

The arrangement of the frequency converter circuit represented in FIG. 5 is an example of the circuit structure in which the mixer circuit is made of the foregoing Gilbert cell and the output amplifier is made of the push-pull amplifier illustrated in FIG. 4. The base of upper transistor Q 31 and the base of lower transistor Q 32 of the push-pull amplifier shown in FIG. 5 are supplied with predetermined bias voltages from first bias circuit 31 and second bias circuit 32, so that each transistor will operate around a predetermined operating point. Further, the two frequency converted signals provided from the mixer circuit are supplied to the bases of upper transistor Q 31 and lower transistor Q 32 through capacitors C4 and C5, respectively.

In this circuit structure, the two frequency converted signals supplied from the mixer circuit are entered to upper transistor Q 31 and lower transistor Q 32, the difference signal of the two frequency converted signals is amplified by the push-pull amplifier and the amplified difference signal is supplied from the junction node between the upper and lower transistors Q 31 and Q 32 as a frequency-converted output signal.

For reference, FIG. 2 to FIG. 5 illustrate the examples of the circuit structures in which an IF signal (IF) enters the input signal amplifier section of the mixer circuit, an LO signal (LO) enters the switch section and an RF signals are supplied as a frequency converted signal and a frequency-converted output signal. When it is intended to take out an IF signal from the frequency converter circuit, the IF signal can be generated, for example, by entering an RF signal to the input signal amplifier section and also entering an LO signal to the switch section.

In the conventional frequency converter circuit, the differential amplifier circuit shown in FIG. 3 has been widely employed as an output amplifier, as described above. A problem encountered, however, has been that realizing the reduction of power consumption will be difficult, because substantially the same or larger amount of the consumption current as the mixer circuit is required to attain a desired gain of the differential amplifier circuit.

However, if the push-pull amplifier is used as an output amplifier of the frequency converter circuit, a problem encountered has been that the input impedances of the upper and lower transistors differ from each other.

Explanation below is presented regarding the input impedance of the push-pull amplifier referring to FIG. 6.

FIG. 6 is an equivalent circuit of the upper transistor of the push-pull amplifier represented in FIG. 4.

The symbol r_{b} shown in FIG. 6 stands for the base resistance of the upper transistor, I_{b} stands for the base current. Further, r_{π} stands for the emitter resistance of the upper transistor, C_{π} for the emitter capacitance, gₘ for the mutual conductance and β for the current gain.

Now, let the impedance of the lower transistor, which operates as a load impedance of the upper transistor, be Z_{L}. Then, input voltage Vᵢ and emitter impedance of the upper transistor Z_{E} can be represented as the following equations (1) and (2):

$$\begin{matrix}{V}_{i} = {r}_{b} ⨯ {I}_{b} + {Z}_{E} ⨯ {I}_{b} + {Z}_{L} ⨯ ( {I}_{b} + {g}_{m} ⨯ {Z}_{E} ⨯ {I}_{b} ) & ( 1 ) \\ {Z}_{E} = \frac{{r}_{π} ( 1 - j ω {r}_{π} {C}_{π} )}{1 + {ω}^{2} {r}_{π}^{2} {C}_{π}^{2}} & ( 2 )\end{matrix}$$

Accordingly, input impedance Zᵢ₁ of the upper transistor is represented by the equation (3) below.

$${Z}_{i 1} = \frac{{V}_{i}}{{I}_{b}} = {r}_{b} + {Z}_{E} + {Z}_{L} ⨯ ( 1 + {Z}_{E} ⨯ \frac{β}{{r}_{π}} ) \qquad ( 3 )$$

Input impedance Zᵢ₂ of the lower transistor, which is emitter-grounded, can be represented by the equation (4) below.
Zᵢ₂=r_{b}+Z_{E} (4)

It is known from the comparison of equations (3) and (4) that input impedance Zᵢ₁ of the upper transistor is larger than input impedance of the lower transistor Zᵢ₂ by the value of the third term on the right-hand side of equation (3),

$${Z}_{L} ⨯ ( 1 + {Z}_{E} ⨯ \frac{β}{{r}_{π}} ) .$$

For this reason, employing the push-pull amplifier shown in FIG. 4 as an output amplifier of the frequency converter circuit results in an unbalanced load impedance as viewed from the output side of the mixer circuit, causing the phases and amplitudes of the LO signal components supplied from the two output terminals of the mixer circuit to be incoincident with each other. Consequently, a high-level LO signal component is provided as output from the output amplifier.

While a push-pull amplifier is featured by the operation with a smaller consumption current and its feasibility of a higher gain than a differential amplifier circuit, it is difficult to use the push-pull amplifier as an output amplifier of the frequency converter circuit because of its unbalanced input impedances and thus the push-pull amplifier has not been employed so often as the differential amplifier circuit.

It is an object of the present invention to provide a frequency converter circuit having an output amplifier that operates with a reduced consumption current and a high gain without increasing an LO signal component that possibly leaks into the output signal.

### DISCLOSURE OF THE INVENTION

In order to achieve the object of the present invention, the frequency converter circuit of the present invention has, as an output amplifier, a push-pull amplifier that allows operating with a reduced consumption current and providing a high gain. Further, the push-pull amplifier of the present invention is configured to have a voltage drop circuit for lowering the potential of the collector of the upper transistor to the level lower than the power supply potential. The voltage drop circuit is configured to have, for example, a resistor inserted between the collector of the upper transistor and the power supply.

In the push-pull amplifier provided with this voltage drop circuit, the collector of the upper transistor is supplied with a potential lower than the power supply potential on account of the operation of the voltage drop circuit. This causes the current gain β of the upper transistor to decrease, resulting in decrease in the value of the third term on the right-hand side of equation (3). As a result, the input impedance of the upper transistor approaches the input impedance of the lower transistor, thereby improving (compensating) the unbalance of the input impedances.

In the frequency converter circuit of the present invention provided with the above push-pull amplifier as an output amplifier, the unbalance of the load impedances of the mixer is improved, thereby blocking an increase in the signal component of the local oscillator frequency to leak into the frequency-converted output signal of the frequency converter circuit.

For this reason, it is feasible to realize a frequency converter circuit provided with an output amplifier operable with a reduced consumption current and easy in realizing a high gain, without increasing the leakage of the signal component of the local oscillator frequency into the frequency-converted output signal.

The arrangement of the voltage drop circuit having a resistor inserted between the power supply and the collector of the upper transistor, in particular, is simple in the circuit structure to result in avoiding an increase in the circuit scale of the frequency converter circuit.

### BRIEF EXPLANATION OF THE DRAWINGS

FIG. 1 is a block diagram illustrating a typical configuration of the frequency converter circuit;

FIG. 2 is a circuit diagram representing the configuration of the Gilbert cell employed for a mixer circuit;

FIG. 3 is a circuit diagram representing the configuration of a conventional frequency converter circuit having a differential amplifier employed as an output amplifier;

FIG. 4 is a circuit diagram representing the configuration of a conventional push-pull amplifier employed as an output amplifier;

FIG. 5 is a circuit diagram representing the configuration of a conventional frequency converter circuit using a push-pull amplifier shown in FIG. 4 as an output amplifier;

FIG. 6 is an equivalent circuit diagram of the upper transistor of the push-pull amplifier shown in FIG. 4;

FIG. 7 is a circuit diagram representing an example of an arrangement of the output amplifier employed in the frequency converter circuit according to the present invention;

FIG. 8 is a block diagram representing the configuration of the frequency converter circuit provided with the output amplifier shown in FIG. 7;

FIG. 9 is a circuit diagram representing an example of the configuration of the frequency converter circuit according to the present invention;

FIG. 10 is a graph representing the gain, noise figure and P1 dB characteristics plotted against the value of resistor Ri of the frequency converter circuit shown in FIG. 9;

FIG. 11 is a graph representing the input impedance characteristics plotted against the value of resistor Ri of the output amplifier shown in Fit. 9;

FIG. 12 is a circuit diagram representing an example of the configuration of the frequency converter circuit according to the present invention using a diode in the output amplifier; and

FIG. 13 is a circuit diagram representing an example of the configuration of the frequency converter circuit according to the present invention using a single-balance circuit in the mixer circuit.

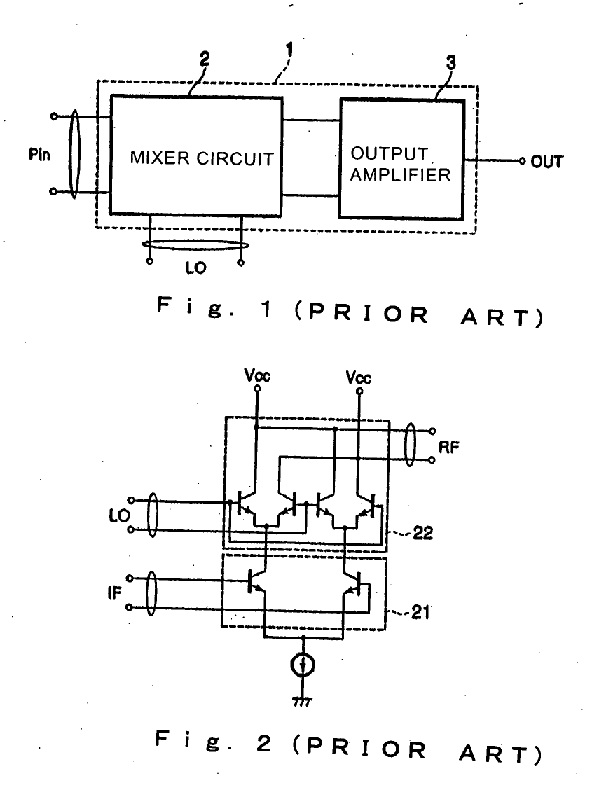

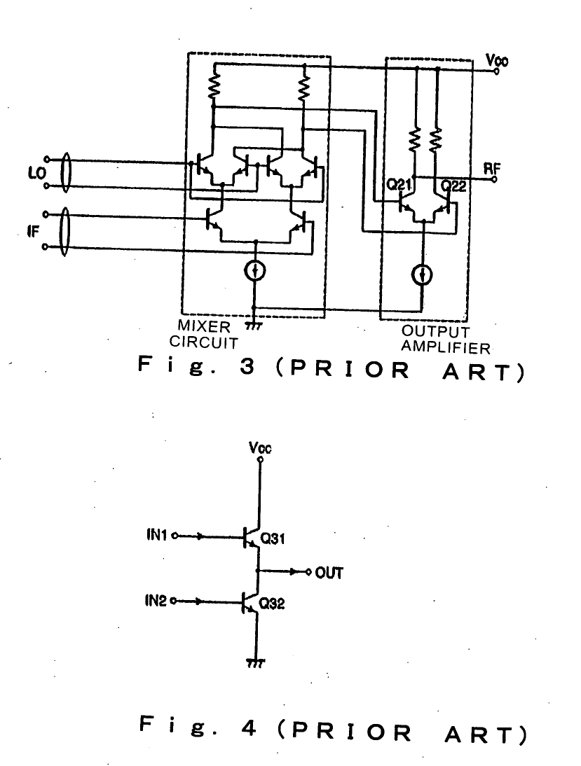

### BEST MODE FOR CARRYING OUT THE INVENTION

Explanation next is presented regarding the present invention referring to the drawings.

The frequency converter circuit of the present invention employs, as an output amplifier, a push-pull amplifier that allows a low consumption-current and high-gain operation.

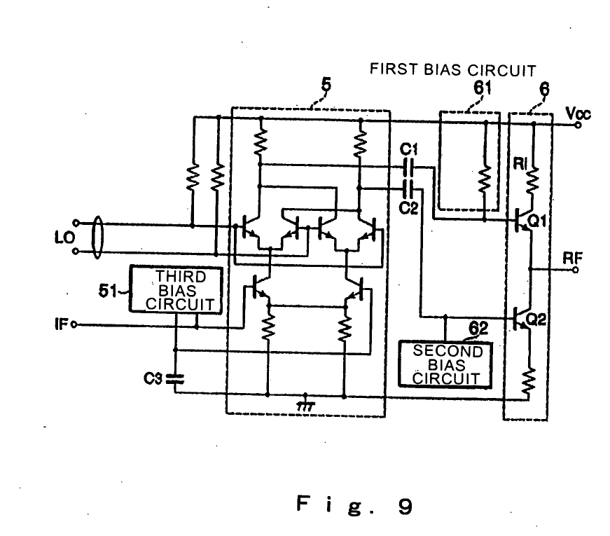

As represented in FIG. 7, the push-pull amplifier of the present invention is configured so as to comprise: upper transistor (a first transistor) Q1 having a collector supplied with a predetermined voltage; lower transistor (a second transistor) Q2 with a grounded emitter; and a voltage drop circuit 4 for dropping the collector potential of upper transistor Q1 to the lower level than that of the power supply; wherein the emitter of upper transistor Q1 and the collector of the lower transistor Q2 are connected to each other.

Voltage drop circuit 4 is structured, for example, to have resistor Ri inserted between the collector of upper transistor Q1 and power supply Vcc, as shown in FIG. 7.

By employing this push-pull amplifier as an output amplifier of the frequency converter circuit as represented in FIG. 8, the unbalance in the load impedance as viewed from the output side of the mixer circuit is improved, whereby an increase in the LO signal component that leaks into the frequency-converted output signal of the frequency converter circuit is blocked.

Now, explanation regards the reason that the lowering of the collector potential of upper transistor Q1 of the push-pull amplifier to the level lower than the potential of the power supply improves the unbalance between the input impedances of upper and lower transistors Q1, Q2.

As represented in FIG. 7, when the collector potential of upper transistor Q1 is lowered below the level of the power supply potential by inserted resistor Ri as voltage drop circuit 4 between power supply Vcc and the collector of upper transistor Q1 of the push-pull amplifier, the base-collector voltage of upper transistor Q1 is decreased. Because a reverse voltage is applied across the pn junction of the base and collector of upper transistor Q1, the lowering of the base-collector voltage causes reduction of the width of the depletion layer in the junction, thereby increasing the parasitic capacitance C_{bc} between the base and collector.

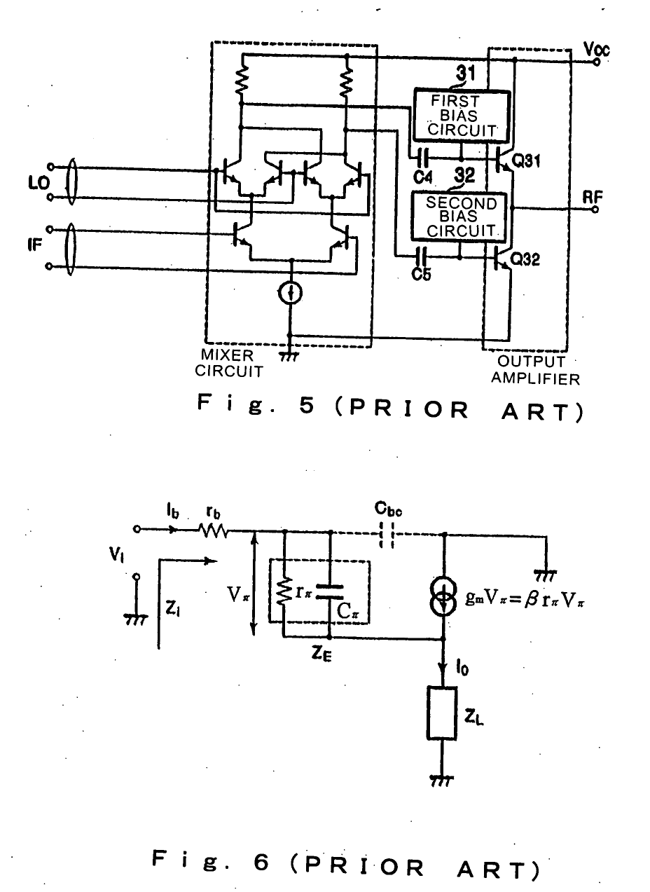

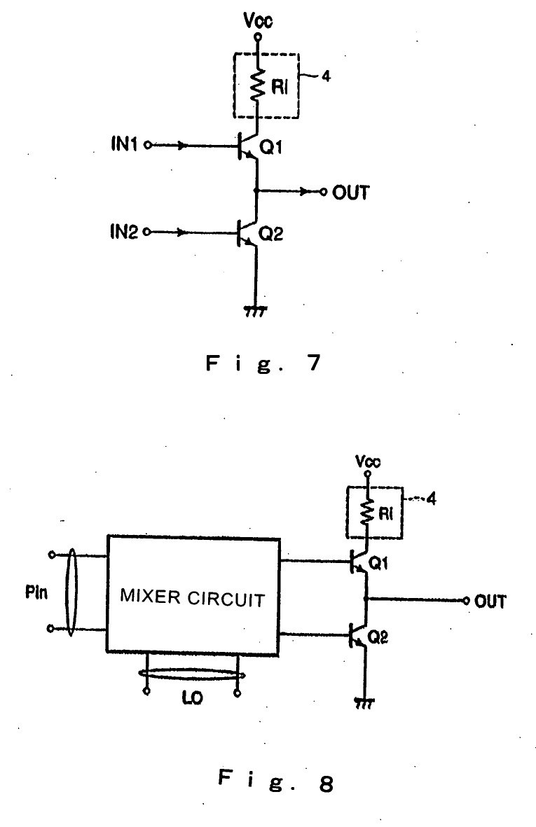

As base-collector parasitic capacitance C_{bc} increases, the impedance of the path (C_{bc}) represented by the dotted line of FIG. 6 (the equivalent circuit of the upper transistor) decreases, which causes the base-collector current to increase.

In this process, because the base-emitter voltage does not change, the base current, i.e., the sum of the base-emitter current and base-collector current, increases by the increase in the base-collector current.

Consequently, the current gain β of upper transistor Q1 is reduced entailing an decrease in the value of the third term on the right-hand side of the above equation (3), which results in the input impedance Zᵢ₁ of upper transistor Q1 approaching the input impedance Zᵢ₂ of lower transistor Q2. As a result, an unbalance between the input impedances of the upper and lower transistors Q1, Q2 is improved.

Although the collector potential of upper transistor Q1 of the push-pull amplifier is lowered relative to the power supply potential, the lowering involves only a drop of the collector potential of the emitter follower, and no deterioration in the gain, the linearity, the noise characteristic, etc is caused. For this reason, it is feasible to make full use of the characteristics of the above push-pull amplifier, and thus the circuit configuration represented in FIG. 8 allows realizing a frequency converter circuit of a low consumption current and a high gain without increasing a leakage of the LO signal component into the frequency-converted output signal.

As shown in FIG. 7 and FIG. 8 in particular, the circuit structure of voltage drop circuit 4 that has resistor Ri inserted between the collector of upper transistor Q1 and power supply Vcc causes no increase in a circuit scale of the frequency converter circuit, because the circuit structure of voltage drop circuit 4 is simple.

Furthermore, if a variable resistor is employed for the resistor Ri inserted between the collector of upper transistor Q1 and the power supply, then it is feasible to regulate by the variable resistor the amount of the LO signal component that leaks into the frequency-converted output signal.

Explanation is next given regarding a specific construction of the frequency converter circuit referring to drawings.

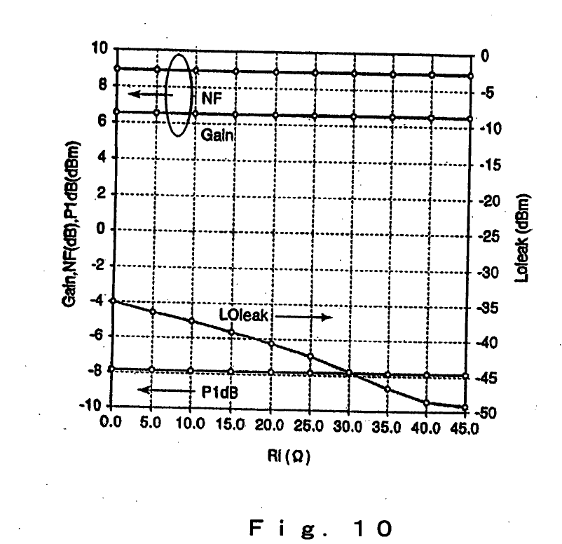

FIG. 9 is a circuit diagram representing a configuration example of the frequency converter circuit of the present invention. Specifically, FIG. 9 represents a configuration example of the frequency converter circuit used for a transmitting system adapted for upconversion from an IF signal to an RF signal through the use of an LO signal.

As shown in FIG. 9, the frequency converter circuit of the present invention is configured to have mixer circuit 5 through the use of a Gilbert cell and output amplifier 6 through the use of a push-pull amplifier shown in FIG. 7.

Predetermined bias voltages are supplied from first bias circuit 61 and second bias circuit 62 to the bases of upper transistor Q1 and lower transistor Q2, respectively, of the push-pull amplifier to operate the respective transistors at predetermined operation points. Further, the two frequency converted signals provided from mixer circuit 5 are entered through capacitor C1, C2 into the bases of upper transistor Q1 and lower transistor Q2, respectively.

Mixer circuit 5 shown in FIG. 9 is configured to supply an input signal (IF) to exclusively one of the input terminals of the input signal amplifier section with other input terminal thereof grounded through capacitor C3. In addition, the two input terminals of the input signal amplifier section are supplied with a predetermined bias voltage from third bias circuit 51. The LO signal is entered to the switch section of mixer circuit 5.

Mixer circuit 5 shown in FIG. 9 is intended to frequency-convert an input signal of an IF to an RF signal using an LO signal, wherein the two frequency converted signal provided from mixer circuit 5 are supplied to upper transistor Q1 and lower transistor Q2 of the push-pull amplifier, by which the difference signal is amplified. The amplified difference signal is supplied as a frequency-converted output signal.

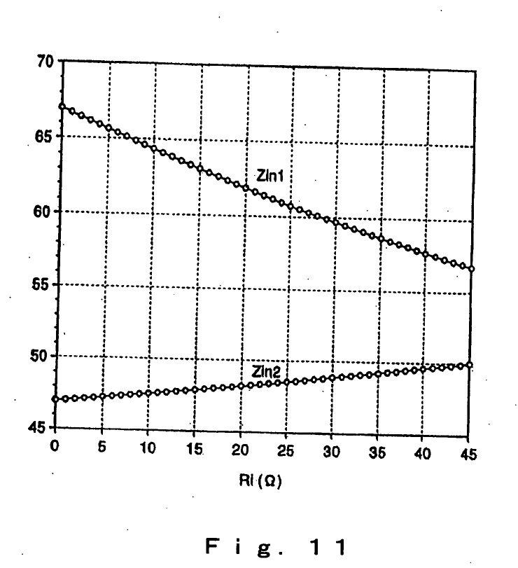

FIG. 10 represents the profiles of LO leak (LOleak), gain (Gain), noise figure (NF), and 1 dB compression point (P1 dB) at an output frequency 5 GHz plotted against the resistor Ri of the frequency converter circuit shown in FIG. 9. For reference, in FIG. 10, the left-side ordinate represents Gain, NF and P1 dB and the right-side ordinate represents the quantity of LOleak. Further, FIG. 10 shows the characteristics over the range to the voltage drop of 0.2 V across resistor Ri inserted between power supply Vcc and the collector of upper transistor Q1 of the push-pull amplifier.

FIG. 10 shows that the amount of leakage of the LO signal component into the frequency-converted output signal (the LO leakage amount) decreases as the value of resistor Ri increases in the frequency converter circuit of the present invention, attaining, for example, an improvement of about 13 dBm when Ri=45 Ω as compared to the case where resistor Ri is lacked. The figure shows, on the other hand, that the Gain, NF and P1 dB of the output amplifier are substantially invariant, and thus the provision of resistor Ri affects no significant influence on these parameters.

The consumption current is about 5 mA when the push-pull amplifier of the present invention shown in FIG. 9 is used and is about 12 mA when a differential amplifier is used for the output amplifier to obtain the same gain. Thus, the consumption current of the push-pull amplifier according to the present invention is no more than half as compared to the differential amplifier, which shows that the push-pull amplifier according to the present invention is advantageous for achieving the reduction of the consumption current.

FIG. 11 shows variations of input impedance Zi1 of the upper transistor and input impedance Zi2 of the lower transistors, respectively, plotted against the value of resistor Ri of the push-pull amplifier according to the present invention. For reference, FIG. 11 represents the characteristics over the range of the voltage drop to 0.2 V across resistor Ri, just like FIG. 10.

FIG. 11 shows that input impedance Zᵢ₁ of upper transistor Q1 decreases with an increase in the value of resistor Ri to approach the value of input impedance Zi2 of lower transistor Q2. This accords with the above explanation and shows that the voltage drop across resistor Ri compensates the unbalance of the input impedances in the push-pull amplifiers.

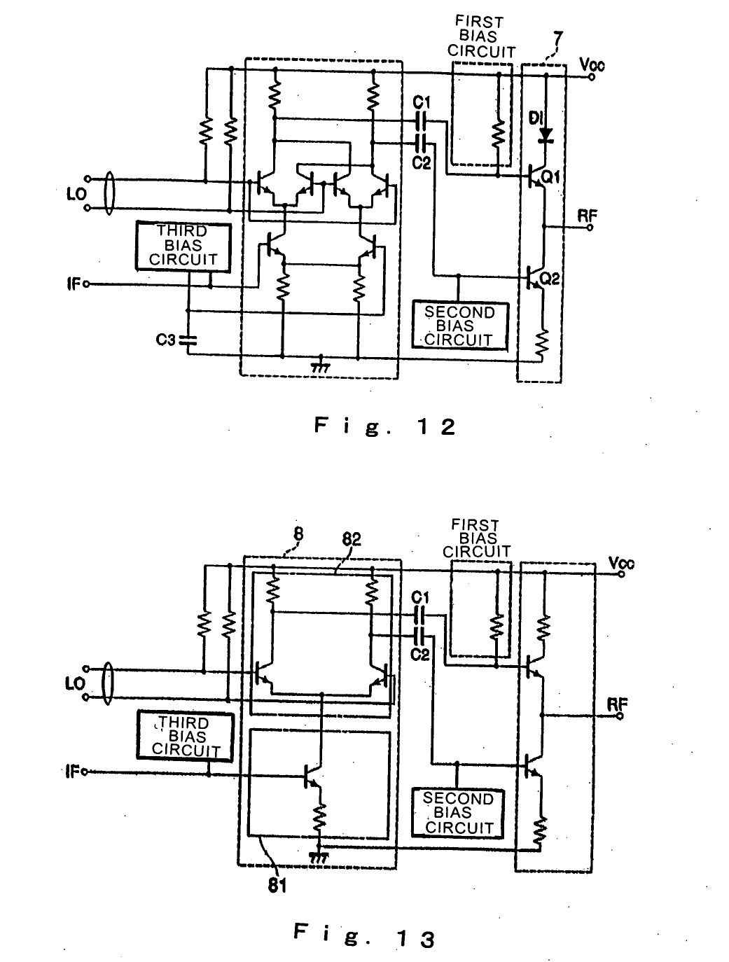

Further, while the above explanation describes a configuration of inserting resistor Ri between power supply Vcc and the collector of upper transistor Q1 as a voltage drop circuit provided in the push-pull amplifier of the present invention, the voltage drop circuit can be configured to have diode D1 with the anode connected to the power supply Vcc and the cathode connected to the collector of upper transistor Q1 to have the forward direction directed from power supply Vcc to the collector of upper transistor Q1, just like the output amplifier 7 shown in FIG. 12.

In addition, while the above explanation describes, as an example, the configuration of using a Gilbert cell, which is a double-balance mixer circuit, as a mixer circuit provided in the frequency converter circuit of the present invention, it is also possible to employ single-balance mixer circuit 8 as shown in FIG. 13.

Single-balance mixer circuit 8 shown in FIG. 13 is configured to have input signal amplifier section 81 that voltage-to-current converts an input signal and also switch section 82 configured to be a differential circuit, to provide the result of mixing (multiplying) an input signal (IF) and an LO signal together as a frequency converted signal. This arrangement also allows the LO signal components of the same phase and also the same amplitude to be provided from the two output terminals, and thus taking out the difference signal of the signals provided from the two output terminals involves the compensation of the LO signal components for each other.

In addition, while the above explanation describes an example of the arrangement to apply the output amplifier of the present invention to the frequency converter circuit for up-converting an IF signal to an RF signal through the use of an LO signal, it is also possible to apply the output amplifier of the present invention to the frequency converter circuit for down-converting an RF signal to an IF signal through the use of an LO signal.

1. A frequency converter circuit comprising:
a mixer circuit that converts a frequency of an input signal through the use of a local oscillator frequency signal; and
an output amplifier made up of a push-pull amplifier provided with,
a first transistor to which a predetermined voltage higher than a ground potential is supplied from a collector,
a second transistor having a grounded emitter and a collector connected to an emitter of said first transistor, and
a voltage drop circuit adapted for providing a potential lower than the potential of a power supply to the collector of said first transistor,
wherein said push-pull amplifier being adapted for amplifying a difference signal of two signals respectively supplied from said mixer circuit and entered into the base of said first transistor and a base of said second transistor and providing an amplified difference signal as output from a junction of said emitter of the first transistor and said collector of the second transistor.

2. The frequency converter circuit according to claim 1, wherein said voltage drop circuit has a resistor inserted between the collector of said first transistor and said power supply.

3. The frequency converter circuit according to claim 1, wherein said voltage drop circuit has a variable resistor inserted between the collector of said first transistor and said power supply.

4. The frequency converter circuit according to claim 1, wherein said voltage drop circuit has a diode inserted between the collector of said first transistor and said power supply, said diode having a forward direction directed in the direction from said power supply toward the collector of said first transistor.

5. (canceled)

6. The frequency converter circuit according to claim 1, wherein said mixer circuit is of the double-balance type.

7. The frequency converter circuit according to claim 1, wherein said mixer circuit is of the single-balance type.

8. The frequency converter circuit according to claim 1, wherein said mixer circuit is adapted to convert said input signal to a signal having a frequency higher than that of said input signal.

9. The frequency converter circuit according to claim 1, wherein said mixer circuit is adapted to convert said input signal to a signal having a frequency lower than that of said input signal.
